(19) United States
(12) Patent Application Publication
(10) Pub. No.: US 2024/0121073 A1
(43) Pub. Date: Apr. 11, 2024

(54) REDUCING EYE ASYMMETRY CAUSED BY VOLTAGE VARIATION IN A CLOCK AND DATA RECOVERY CIRCUIT OR DELAY LOCKED LOOP

(71) Applicant: QUALCOMM Incorporated, San Diego, CA (US)

(72) Inventors: Jianwen YE, Apex, NC (US); Julian PUSCAR, Cary, NC (US)

(21) Appl. No.: 17/963,970

(22) Filed: Oct. 11, 2022

(51) Int. Cl. H04L 7/033; H03L 7/08; H03L 7/081; H04L 7/00

(52) U.S. Cl. CPC H04L 7/0337; H03L 7/0807; H03L 7/0812; H04L 7/0025

(57) ABSTRACT

A data communication interface has a delay-locked loop configured to generate a receive clock signal based on timing information provided by a signal received over a clock channel of a data communication link, a phase interpolator configured to provide a phase-shifted clock signal by phase-shifting one or more edges in the receive clock signal based on timing of transitions in a data signal received over a data channel of the data communication link, a clock and data recovery circuit configured to capture data from the data signal using the phase-shifted clock signal, and a calibration circuit. The calibration circuit is configured to calibrate the delay-locked loop while the clock and data recovery circuit is in an idle state, recalibrate the delay-locked loop when the clock and data recovery circuit is activated, and calibrate the clock and data recovery circuit after recalibrating the delay-locked loop.

### TECHNICAL FIELD

The present disclosure generally relates to equalization on high-speed interfaces and, more particularly, to calibration circuits provided in a receiver.

### BACKGROUND

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Wireless devices may include a high-speed bus interface for communication of signals between hardware components.

High-speed serial buses offer advantages over parallel communication links when, for example, there is demand for reduced power consumption and smaller footprints in integrated circuit (IC) devices. In a serial interface, data is converted from parallel words to a serial stream of bits using a serializer and is converted back to parallel words at the receiver using a deserializer. For example, the high-speed bus interface may be implemented using a Peripheral Component Interconnect Express (PCIe) bus, Universal Serial Bus (USB) or Serial Advanced Technology Attachment (SATA), among others.

IC devices may include memory interfaces that have physical layer circuits that are configured to read and write double data rate random access memory devices. Increased demands for higher data rates require tight timing between circuits within the memory interface. Performance, accuracy or reliability of the memory interface may depend on calibration and training procedures that can accommodate voltage drift and other variances that can impact the operation of the memory interface. Therefore, there is an ongoing need for new techniques that provide reliable training and calibration techniques for components used to receive clock and data signals over high-speed data links.

### SUMMARY

Certain aspects of the disclosure relate to systems, apparatus, methods and techniques that can be used in equalizing circuits in a transmitter coupled to a serial data link. Certain aspects provide flexible configuration of equalizing circuits to enable different modes of operation. The modes of operation can include high frequency, high data rate operation and low-power modes that can be configured through control of clock signals used to sample data from the serial data link.

In various aspects of the disclosure, a data communication interface has a delay-locked loop configured to generate a receive clock signal based on timing information provided by a signal received over a clock channel of a data communication link, a phase interpolator configured to provide a phase-shifted clock signal by phase-shifting one or more edges in the receive clock signal based on timing of transitions in a data signal received over a data channel of the data communication link, a clock and data recovery circuit configured to capture data from the data signal using the phase-shifted clock signal, and a calibration circuit. The calibration circuit is configured to calibrate the delay-locked loop while the clock and data recovery circuit is in an idle state, recalibrate the delay-locked loop when the clock and data recovery circuit is activated, and calibrate the clock and data recovery circuit after recalibrating the delay-locked loop.

In various aspects of the disclosure, an apparatus has means for generating a receive clock signal, means for providing a phase-shifted clock signal, means for capturing data from a data signal and means for calibrating one or more circuits of the apparatus. The means for generating the receive clock signal includes a delay-locked loop responsive to timing information provided by a signal received over a clock channel of a data communication link. The means for providing a phase-shifted clock signal includes a phase interpolator configured to by phase-shift one or more edges in the receive clock signal based on timing of transitions in a data signal received over a data channel of the data communication link. The means for capturing data from the data signal includes a clock and data recovery circuit responsive to the phase-shifted clock signal. The means for calibrating one or more circuits of the apparatus is configured to calibrate the delay-locked loop while the clock and data recovery circuit is in an idle state, recalibrate the delay-locked loop when the clock and data recovery circuit is activated, and calibrate the clock and data recovery circuit after recalibrating the delay-locked loop.

In various aspects of the disclosure, a method includes generating a receive clock signal using a delay-locked loop responsive to timing information provided by a signal received over a clock channel of a data communication link, providing a phase-shifted clock signal using a phase interpolator configured to by phase-shift one or more edges in the receive clock signal based on timing of transitions in a data signal received over a data channel of the data communication link, capturing data from the data signal using a clock and data recovery circuit responsive to the phase-shifted clock signal, calibrating the delay-locked loop while the clock and data recovery circuit is in an idle state, calibrating the delay-locked loop when the clock and data recovery circuit is activated, and calibrating the clock and data recovery circuit after recalibrating the delay-locked loop.

In certain aspects, the calibration circuit is further configured to determine a first delay-locked loop calibration code (DLL calibration code) when calibrating the delay-locked loop while the clock and data recovery circuit is in the idle state, determine a second DLL calibration code while recalibrating the delay-locked loop when the clock and data recovery circuit is activated, determine a phase interpolator code based on a difference between the first DLL calibration code and the second DLL calibration code, and use the phase interpolator code to configure the phase interpolator. The calibration circuit may be further configured to perform at least one additional recalibration of the delay-locked loop, and determine that a power supply voltage has changed when the at least one additional recalibration produces a third DLL calibration that is different from the second DLL calibration code. The calibration circuit may be further configured to determine an updated phase interpolator code based on a difference between a current DLL calibration code and an initial DLL calibration code after determining that the power supply voltage has changed, and use the updated phase interpolator code to configure the phase interpolator. The current DLL calibration code and the initial DLL calibration code may be included in a table of DLL calibration codes that includes the first DLL calibration code and the second DLL calibration code.

In certain aspects, the calibration circuit is further configured to determine that the data communication interface has been reconfigured, and reconfigure the delay-locked loop using a current DLL calibration code that is selected based on an anticipated change in power supply voltage caused by the reconfiguration of the data communication interface. The calibration circuit may be further configured to determine an updated phase interpolator code based on a difference between the current DLL calibration code and an initial DLL calibration code after determining that the power supply voltage has changed, and use the updated phase interpolator code to configure the phase interpolator. The delay-locked loop may be configured with the initial DLL calibration code before the reconfiguration of the data communication interface. The data communication link may include a plurality of data channels. The table of DLL calibration codes may map DLL calibration codes to a plurality of data communication link configurations. Reconfiguration of the data communication interface may cause one or more of the plurality of data channels to be deactivated or causes one or more of the plurality of data channels to be activated.

In certain aspects, the calibration circuit is further configured to incrementally adjust the phase of the phase-shifted clock signal provided by the phase interpolator independently. Phase shifts added to the receive clock signal by a plurality of phase interpolators may be adjusted independently of one another.

### BRIEF DESCRIPTION OF THE DRAWINGS

FIG. 1 illustrates an example of a system-on-a-chip (SOC) in accordance with certain aspects of the present disclosure.

FIG. 2 illustrates an example of a data communication system that may be adapted in accordance with certain aspects of the present disclosure.

FIG. 3 illustrates an eye diagram generated as an overlay of signaling state for multiple bit transmissions.

FIG. 4 illustrates an example of a calibration process in which certain variations in power supply voltage can affect eye opening symmetry.

FIG. 5 includes illustrates eye asymmetry.

FIG. 6 illustrates a calibration technique that may be performed in accordance with certain aspects of this disclosure.

FIG. 7 illustrates a mapping table that maintains DLL calibration codes for various operating states of a data communication interface that is operated in accordance with certain aspects of this disclosure.

FIG. 8 illustrates an example of real-time calibration in accordance with certain aspects of this disclosure.

FIG. 9 illustrates certain aspects of a phase control circuit that may be operated in accordance with certain aspects of this disclosure.

FIG. 10 is a flowchart illustrating an example of a method for calibrating a data communication interface in accordance with certain aspects disclosed herein.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the Figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, notebooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain aspects of the disclosure are applicable to IC devices that provide an interface between core circuits and memory devices. In one example, many mobile devices employ Synchronous Dynamic Random Access Memory (SDRAM), including Low-Power Double Data Rate (DDR) SDRAM, which may be referred to as low-power DDR SDRAM, LPDDR SDRAM or, in some instances, LPDDRx where x describes the technology generation of the LPDDR SDRAM. Later generations of LPDDR SDRAM designed to operate at higher operating frequencies.

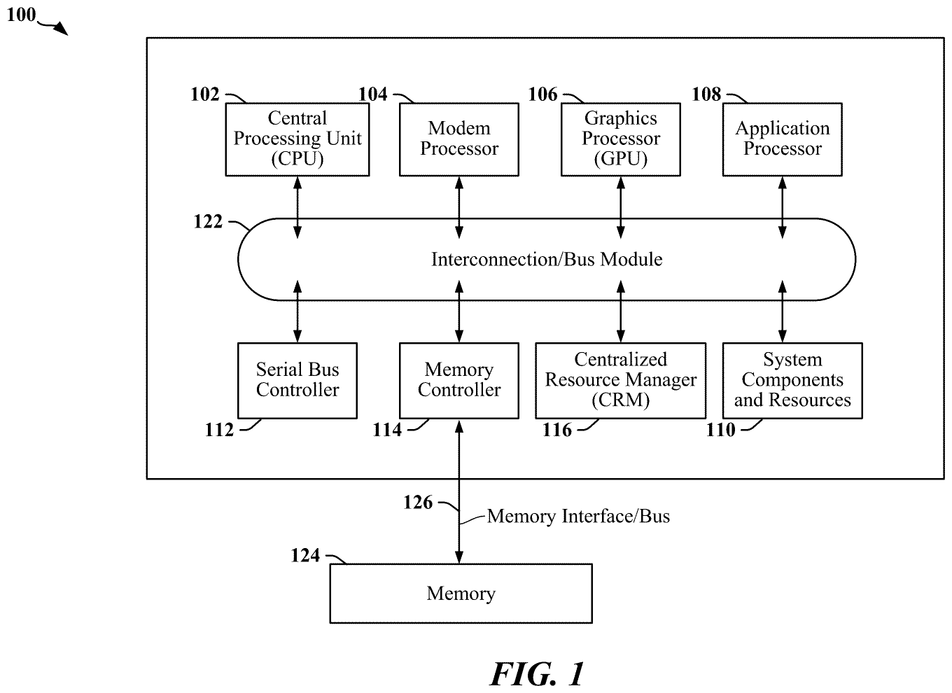

FIG. 1 illustrates example components and interconnections in a system-on-chip (SoC) 100, including a memory interface/bus 126, that may be suitable for implementing certain aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) or other serial bus controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture. Communications may also be provided by advanced interconnects, such as high performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The memory controller 114 may be a specialized hardware module configured to manage the flow of data to and from a memory 124 via the memory interface/bus 126.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

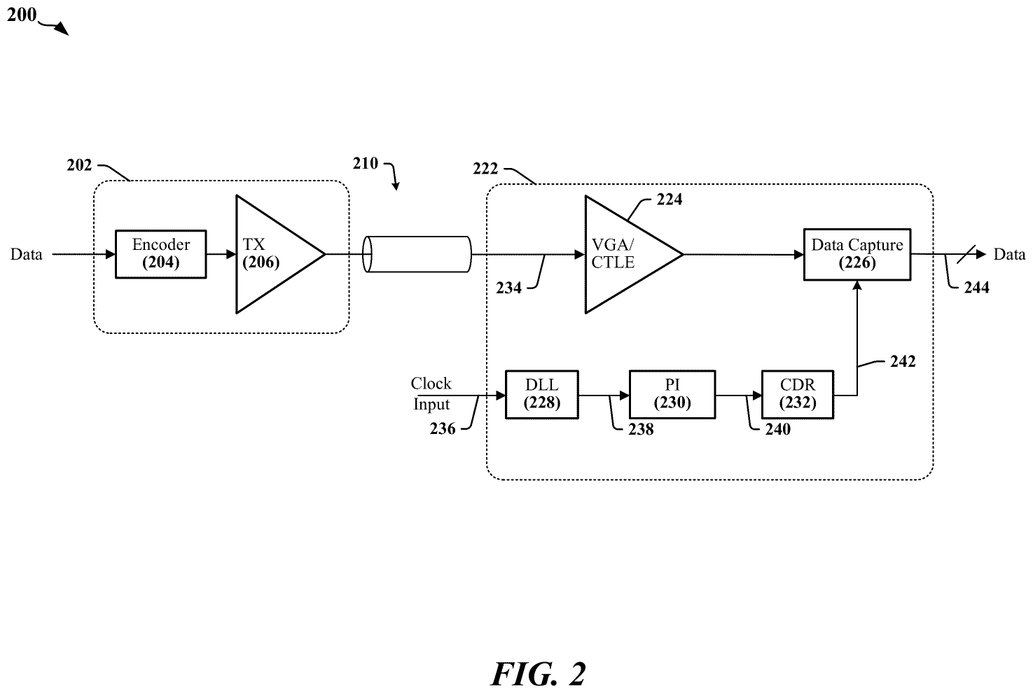

FIG. 2 illustrates an example of a data communication system 200 that may be adapted in accordance with certain aspects of the present disclosure. The data communication system 200 includes a transmitter 202, a data communication channel 210, and a receiver 222. The transmitter 202 may be provided in a first device that is configured to transmit a data signal to a second device. The data communication channel 210 provides a transmission medium through which a transmitted data signal propagates from the first device to the second device. The receiver 222 is provided in the second device and may be configured to receive and process a received data signal 234.

In one example, the transmitter 202 includes a serializer 204 configured to provide a stream of data for transmission through the data communication channel 210. The transmitter 202 further includes a transmit driver 206 configured to generate the transmitted data signal based on the serial data for transmission to the receiver 222 over the data communication channel 210.

The data communication channel 210 may be implemented using any type of transmission medium by which a data signal can propagate from the transmitter 202 to the receiver 222. Examples of the data communication channel 210 includes one or more metallization traces (which may include one or more vias) on a printed circuit board (PCB), stripline, microstrip, coaxial cable, twisted pair, etc.

The receiver 222 includes a variable gain amplifier (VGA) with a continuous time linear equalizer (CTLE) (the VGA/CTLE 224), which may be implemented in a single stage or multiple stages, a clock data recovery circuit (the CDR circuit 232), and a deserializer 226. CTLE may refer to techniques for boosting the higher frequency components of the signal at the receiver in order to bring all frequency components of the signal to a similar amplitude, improving jitter and eye-diagram performance. As disclosed herein, the VGA/CTLE 224 is configured to perform equalization and amplification of the received data signal. The CDR circuit 232 is configured to recover clock information associated with the data signal 234 and to generate a data recovery clock signal 242 that can be used to sample or otherwise recover the serial data from the data signal. The deserializer 226 is configured to convert a serial data stream back into parallel data 244.

The received data signal 234 or a received clock signal may be distorted when it arrives at the receiver 222 through the data communication channel 210. Distortion may arise for various reasons including impedance mismatches in the data communication channel 210, interference and reflected energy. Signal distortion can make it difficult to recover the clock information and the data by the CDR circuit 232 and can limit the window of stability during which data can be reliably sampled. In some examples, distortion in the received data signal 234 caused by high frequency attenuation can be addressed by the VGA/CTLE 224, which may be configured to perform equalization and amplification that increases the high frequency components of the data signal 234 in order to increase the data rate at which the data may be sent through the data communication channel 210 and reliably recovered at the receiver 222. In some examples, amplification may be performed using high-speed amplifiers that are implemented using current-mode logic (CML) structures. CML structures may also be referred to as source-coupled logic (SCL) structures.

The CDR circuit 232 may be configured to generate a data recovery clock signal 242 that has edges (transitions) that are positioned in time within the window of stability during which data can be reliably sampled. The data recovery clock signal 242 may be provided in two or more phase versions that can be used directly by a data recovery circuit, including the illustrated deserializer 226. In the illustrated example, a clock input 236 is provided to a delay locked loop (the DLL 228) that provides a receiver clock signal 238. In some examples, the receiver clock signal 238 is provided as multiple phase single-ended signals, although it may alternatively be provided as multiple phase differential signals. The receiver clock signal 238 can be used to derive the data recovery clock signal 242. In one example, the clock input 236 is a version of a clock signal received from the transmitter 202. The DLL 228 may be configured to generate the receiver clock signal 238 with a different frequency than the frequency associated with the clock input 236. For example, the DLL 228 may be configured to double or quadruple the frequency associated with the clock input 236 while preserving correspondence of edges in the clock input 236 with edges in the receiver clock signal 238. In some implementations, a phase interpolator (the PI 230) may be used to generate one or more phase shifted receiver clock signals 240 that are used by the CDR circuit 232. The PI 230 may be configurable to move or reposition edges in the data recovery clock signal 242 within the window of stability to accommodate changes in operating conditions that may be sensitive to the effects of process, voltage and temperature (PVT) variances.

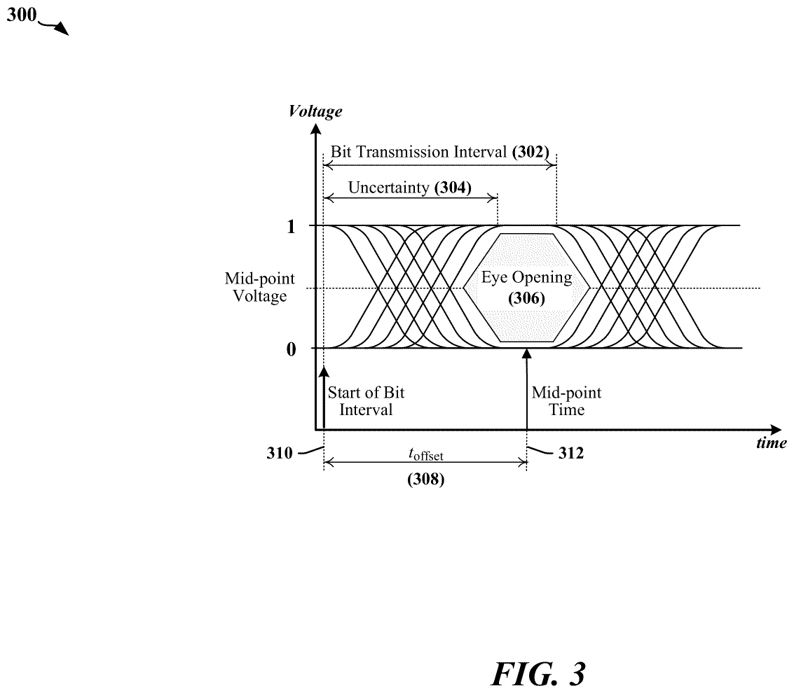

The window of stability during which data can be reliably sampled may be visualized in an eye-diagram. FIG. 3 illustrates an eye diagram 300 generated as an overlay of signaling state for multiple bit transmissions. A bit transmission may occur in one bit transmission interval 302 that may span a full cycle or half-cycle of a transmitter clock signal. A signal transition region 304 represents a time period of uncertainty at the boundary between two symbols where variable signal rise times prevent reliable decoding. State information may be determined reliably in a region defined by an eye opening 306 that encompasses the window of stability, and that represents the period of period in which signaling state is stable and the bit value can be reliably sampled and captured. The eye opening 306 may define a region in which mid-point crossings do not occur and a receiver or decoder can delineate a window of stability within the eye opening 306. The window of stability defines a region within the eye opening 306 in which the signaling states can be reliably distinguished, and may be based on minimum and maximum voltage thresholds. Information can be reliably sampled, demodulated or decoded from a data signal within the window of stability. The eye opening 306 may be narrowed along the time axis by increases in data rate and may be compressed in the voltage axis by ISI and other types of interference and distortion. The eye opening 306 may be narrowed along the time axis when rise times or fall times for a data signal differ.

The concept of periodic sampling and overlaid display of the signal is useful during design, adaptation and configuration of systems which use a clock and data recovery (CDR) circuit that re-creates the received data-timing signal using frequent transitions appearing in the received data. A communication system based on Serializer/Deserializer (SERDES) technology is an example of a system where an eye opening 306 in an eye diagram 300 can be utilized as a basis for judging the ability to reliably recover data. An eye-opening monitor (EOM) may be implemented using one or more comparators that can indicate when the voltage in a channel is sufficiently higher or lower than the mid-point voltage to enable reliable sampling of the signal carried by the channel.

With continued reference to FIGS. 2 and 3, the receiver 222 may be employed in high-speed input/output (I/O) applications to recover timing information from an incoming clock input 236 and to generate a data recovery clock signal 242 that has been phase-aligned or re-timed to receive and/or capture data from the received data signal 234. The data recovery clock signal 242 may be generated by phase aligning a reference clock signal generated by the DLL 228 with transitions in the incoming data. Data may be sampled at a time defined by edges in the data recovery clock signal 242. In the illustrated example, the nominal ideal sampling point occurs at a time corresponding to the mid-point 312 of the eye opening 306. The eye opening 306 begins after the period of uncertainty represented by the signal transition region 304. The nominal ideal sampling point may be defined using the time t (t_{offset} 308) elapsed from the start of a bit transmission interval 310 and the mid-point 312 of the eye opening 306. The nominal ideal sampling point may also be defined as a phase offset provided in the data recovery clock signal 242.

In some instances, transitions in the data recovery clock signal 242 can occur at time or phase offsets that would result in sampling outside the eye opening 306, and errors in data capture can occur. In the ideal symmetric eye diagram 300, the distances from a nominal ideal sampling point, which may be referred to as the CDR locking point, to the two edges of the eye opening 306 should be the same. In some instances, differences in signal rise time and signal fall time can result in an asymmetric eye, which can reduce the tolerance of the receiver 222 to timing jitter and can lead to failure. PVT variances can affect the timing of the edges in the data recovery clock signal 242, and in some systems, variances in voltage can be a primary cause of asymmetric CDR eye. In one example, the voltage of power supply may change when certain circuits are transitioned between idle and active states. Circuits such as the CDR circuit 232 may be placed in an idle or dormant state to conserve power when the data communication channel 210. Other circuits, including the DLL 228, for example, may also be placed in idle or dormant states. Circuits that are used occasionally, such as calibration circuits may be idle or dormant for a majority of the time in which the receiver 222 is enabled. In another example, the active number of data communication channels and corresponding transceivers and data capture circuits can vary as channels are idled or activated.

Symmetry of the eye opening 306 may be affected by power supply voltage variability that reflects a changing number or combination of active circuits and/or communication channels. Symmetry of the eye opening 306 may be affected if power supply voltage variability affects clock and data signal paths unequally. For example, the clock signal path is typically longer than the data signal path and the difference in lengths can cause disparate changes in phase of clock and data signals when voltage changes.

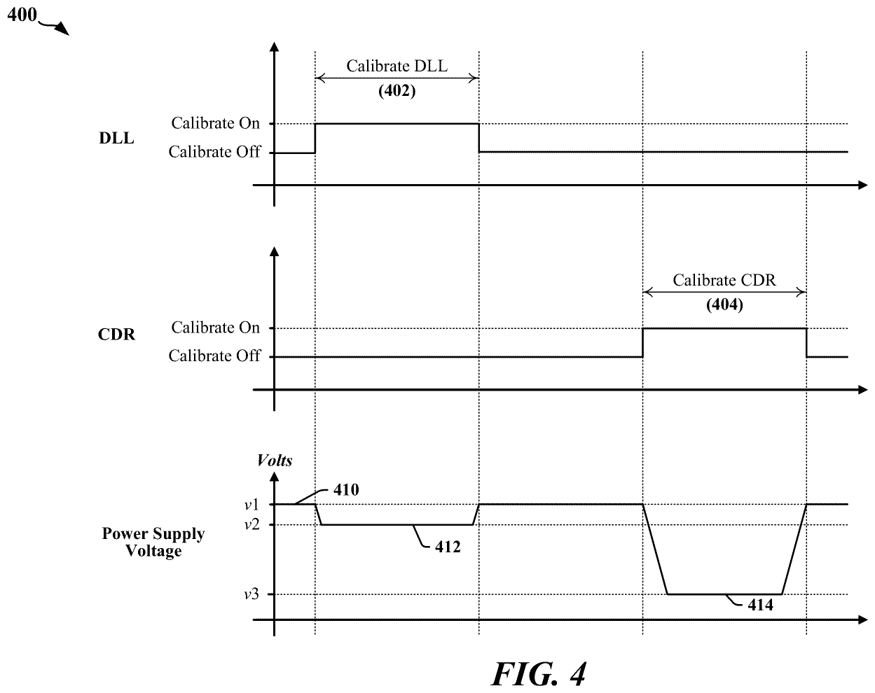

FIG. 4 illustrates an example of a calibration process 400 in which certain variations in power supply voltage can affect eye opening symmetry associated with a communication interface in subsequent receive operations. The calibration processes can be described in relation to the receiver 222 illustrated in FIG. 2. The illustrated variations in power supply voltage can be attributed to the power drawn by different circuits during different phases of a calibration of clock generation circuits in the receiver 222. The calibration may be implemented in different phases to conserve energy by enabling certain circuits to be idled during calibration of other circuits. For example, the CDR circuit 232 may be idled during calibration of the DLL 228 and circuits used during the calibration of the DLL 228 may be idled or disabled during calibration of the CDR circuit 232.

Conventionally, the DLL 228 is the first component to be calibrated. The communication interface is in an idle state, with the power supply having a first voltage level 410. During a DLL calibration period 402, increased power consumption causes the power supply voltage to drop to a second voltage level 412. The difference between the first voltage level 410 and the second voltage level 412 is expected to lie within specified tolerances for the power supply and may amount to a difference of one or two percent. For example, the voltage of a nominal 0.8 volt power supply may drop to 0.79 volts during calibration of the DLL 228. A delay calibration loop may be used to iteratively adjust one or more delays in the DLL 228 until a target frequency is achieved. Calibration of the DLL 228 may yield a binary number (DLL code) that configures the DLL 228 to generate an output clock signal with a desired phase shift. In one example, the DLL code may configure one or more delay elements in the DLL 228. Power consumption may return to the pre-calibration level and the power supply voltage may return to the first voltage level 410.

After a delay or an idle period, a CDR calibration period 404 commences. Power consumption increases, causing the power supply voltage to drop to a third voltage level 414. The difference between the first voltage level 410 and the third voltage level 414 is expected to lie within specified tolerances for the power supply. The third voltage level 414 can be significantly lower than the second voltage level 412 since the CDR circuit 232 typically consumes considerable power. In some implementations, the difference between the first voltage level 410 and the third voltage level 414 can be 3% or greater. For example, the voltage of a nominal 0.8 volt power supply may drop to 0.75 volts during calibration of the CDR circuit 232. Calibration of the CDR circuit 232 may involve determining a binary number (CDR code) that causes the CDR circuit 232 to configure the timing of edges in the data recovery clock signal 242. In one example, the CDR code may configure one or more delays or phase shifts in the PI 230 or CDR circuit 232. In other examples, a PI configuration may be determined or used by the DLL 228 to configure initial delays or phase shifts in the PI 230. In some instances, the PI 230 may be independently calibrated at least initially.

In the example illustrated in FIG. 4, the CDR circuit 232 is calibrated at the third voltage level 414 using a DLL 228 that has been calibrated at the second voltage level 412. This discrepancy between voltages can lead to CDR eye asymmetry.

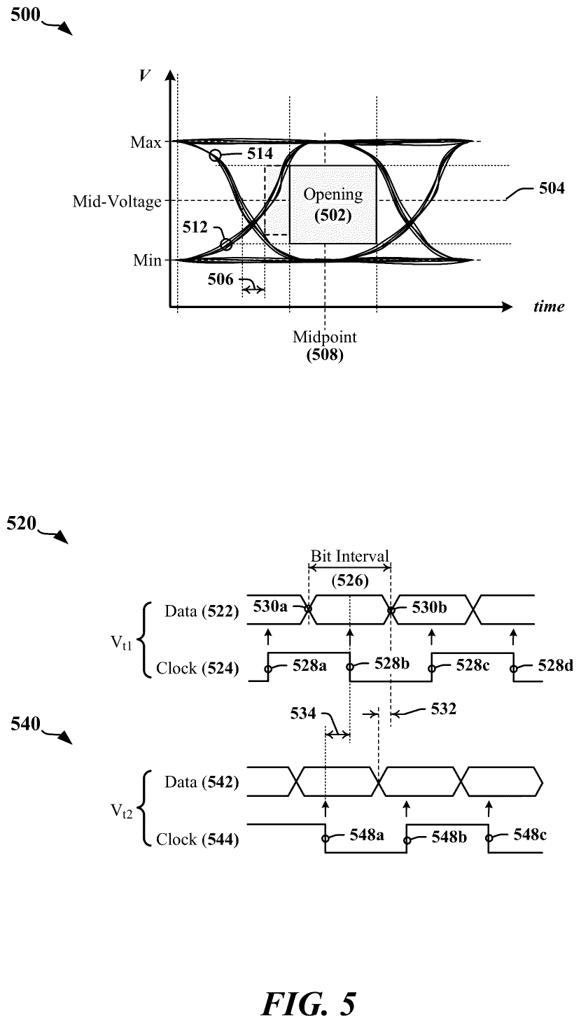

FIG. 5 includes an eye diagram 500 that illustrates eye asymmetry. In the illustrated example, a bit transmission interval is shown with an asymmetric eye opening 502 caused by rising edges 512 that transition more slowly than falling edges, as can be seen from the difference in time 506 between their respective crossings of the mid-voltage level 504. The difference in timing of rising and falling edges results in an eye opening 502 that is not centered on the mid-voltage level 504 or at the midpoint between edges 508.

FIG. 5 also includes timing diagrams 520, 540 that illustrate an example of asymmetry that may be introduced by changes in power-supply voltage. The first timing diagram 520 illustrates timing of data capture at a first point in time using a clock signal 524 generated when a CDR, DLL and PLL are calibrated for the current voltage of the power supply (Vₜ₁). By way of example, edges 528a-528d in the clock signal 524 are ideally positioned to capture corresponding data bits from the data signal 522. For example, edge 528b occurs at the center of bit interval 526 and can reliably capture data in the presence of jitter affecting the leading transition 530a in the data signal 522 or the lagging transition 530b in the data signal 522.

The second timing diagram 540 illustrates the timing of data capture after the power supply voltage has changed to new voltage level (Vₜ₂). Here, the clock signal 544 is generated by a CDR when the DLL and PLL are not calibrated for the new power supply voltage level (Vₜ₂) but remain calibrated for the initial voltage of the power supply (Vₜ₁). The data signal 542 is affected less than the clock signal 544. In the illustrated example, the data signal 542 is delayed by a duration 532 that is less than the duration 534 by which edges 548a-548c in the clock signal 544 are delayed. The edges 548a-548c in the clock signal 524 are misaligned with respect to the bit positions in the data signal 542. This misalignment of edges 548a-548c in the clock signal 524 renders the data capture circuits more susceptible to jitter affecting the leading transition 530a in the data signal 522 than jitter affecting the lagging transition 530b in the data signal 522. The misalignment of edges 548a-548c in the clock signal 524 may be regarded or observed as an asymmetric eye opening.

Certain aspects of the present disclosure relate to calibration and operation of a phase interpolator that can account for variations in power supply voltage and that can reduce asymmetry of the opening in the CDR eye diagram. In one aspect, DLL delay calibration loops can be executed to indicate a loss of calibration after an initial calibration of the DLL 228 has been completed. In some examples, the loss of calibration may be attributable to changes on power supply voltage. When a DLL delay calibration loop indicates loss of calibration, the DLL 228 can be recalibrated by completing the delay calibration loop.

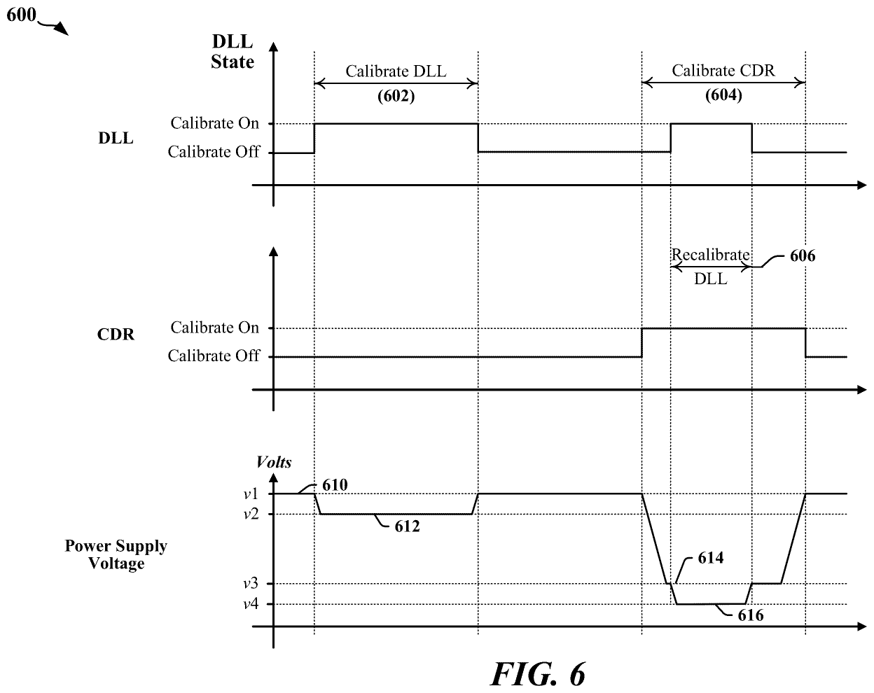

FIG. 6 illustrates an example of a calibration technique 600 that may be performed in accordance with certain aspects of this disclosure. The calibration processes illustrated in FIG. 6 are described in relation to the receiver 222 illustrated in FIG. 2. Variations in power supply voltage can be attributed to the power drawn by different circuits during different phases of a calibration of clock generation circuits in the receiver 222. Energy may be conserved during calibration by idling certain circuits in different calibration phases. For example, the CDR circuit 232 can be idled during calibration of the DLL 228 and some circuits used during the calibration of the DLL 228 may be idled or disabled during calibration of the CDR circuit 232.

An initial calibration of the DLL 228 is performed during a DLL calibration period 602. In the illustrated example, the CDR circuit 232 is idled or dormant and the communication interface is in an idle state, in which no data is being transmitted or received. Current from the power supply is supplied at a first voltage level 610 before the DLL calibration period 602 and drops to a second voltage level 612 when power consumption is increased due to the operation of certain calibration circuits. The difference between the first voltage level 610 and the second voltage level 612 is expected to lie within specified tolerances for the power supply and may amount to a difference of one or two percent. For example, the voltage of a nominal 0.8 volt power supply may drop to 0.79 volts during calibration of the DLL 228. Calibration of the DLL 228 may involve executing a DLL delay calibration loop to determine a binary number that may be referred to herein as a DLL code, and that causes the DLL 228 to generate an output clock signal with a desired phase shift. In one example, the DLL code may configure one or more delays in the DLL 228. Power consumption may return to the pre-calibration level and the power supply voltage may return to the first voltage level 610.

After an idle period, a CDR calibration period 604 commences. Power consumption increases, causing the power supply voltage to drop to a third voltage level 614. The difference between the first voltage level 610 and the third voltage level 614 is expected to lie within specified tolerances for the power supply. The third voltage level 614 can be significantly lower than the second voltage level 612 since the CDR circuit 232 typically consumes considerable power. In some implementations, the difference between the first voltage level 610 and the third voltage level 614 can be 3% or greater. For example, the voltage of a nominal 0.8 volt power supply may drop to 0.75 volts during calibration of the CDR circuit 232. Calibration of the CDR circuit 232 may involve determining a binary number (CDR code) that causes the CDR circuit 232 to configure the timing of edges in the data recovery clock signal 242. In one example, the CDR code may configure one or more delays or phase shifts in the PI 230 or CDR circuit 232.

According to certain aspects of this disclosure, the DLL 228 is recalibrated in a DLL recalibration period 606 while the CDR circuit 232 is active. The initiation of a DLL delay calibration loop within the DLL recalibration period 606 can cause the power supply voltage to drop from the third voltage level 614 to a fourth voltage level 616. In some examples, the power supply voltage offset (vdiff_{DLL}) attributable to a DLL delay calibration loop may be calculated as:

vdiff_{DLL}=v3−v4=v1−v2, Eq. 1

where v1 represents the first voltage level 610, v2 represents the second voltage level 612, v3 represents the third voltage level 614 and v4 represents the fourth voltage level 616.

Recalibrating the DLL 228 at the fourth voltage level 616 can yield a characterization of the size of offset that is needed to compensate the asymmetry due to changes in power supply voltage that can occur when the CDR circuit 232 is activated. The recalibration yields an updated DLL code. The original DLL code, the updated DLL code and/or the difference in value between the DLL codes may be stored by a controller or calibration circuit provided in the communications interface.

In some implementations, the DLL delay calibration loop may be executed to detect power supply changes, and to cause the DLL code to be updated. Updates to the DLL code can enable the nominal data sampling point to be tracked, and a symmetric CDR eye may be maintained after power supply changes using DLL codes stored or accessible by the controller.

In accordance with certain aspects of this disclosure, the PI 230 may be configured to compensate for changes in timing that can result in an asymmetric eye. In one example, a controller may reconfigure a data communication interface in a manner that causes changes to the power supply voltage. The controller may determine a change in phase interpolator configuration based on the values of DLL codes associated with the new and previous data communication interface configurations.

The data communication interface may include a phase interpolator that selects a phase for an output signal by mixing two phase versions of an input signal. The phase of the output signal is selected by weighting the contributions of the two phase versions of an input signal in the output signal. For example, the phase versions of the input signal may be quadrature (I and Q) signals that are separated by a 90° phase shift and the output signal may be generated with a phase shift that can be changed in step intervals. The output signal may have substantially the same phase as the Q signal when the I input signal is weighted at 0% and the Q input signal is weighted at 100%. The phase of the output signal may be modified by stepwise adding and/or removing weight to the inputs.

In one aspect of the disclosure, eye symmetry may be restored by adjusting the phase interpolator to change the phase of the output using a compensation offset, where:

compensation offset=α×[DLLᵥ₄−DLLᵥ₂] Eq. 2

The compensation offset may correspond to a number of steps of phase change used to adjust the phase interpolator. In some examples, each step of phase change increases or decreases phase by a fixed phase angle. It is assumed here that vdiff_{DLL} (see Eq. 1), which represents the power supply voltage increase during DLL calibration, is negligible. That is, v₄≈v₃. In some examples, the term a can be characterized in simulations, empirically and/or during system initialization.

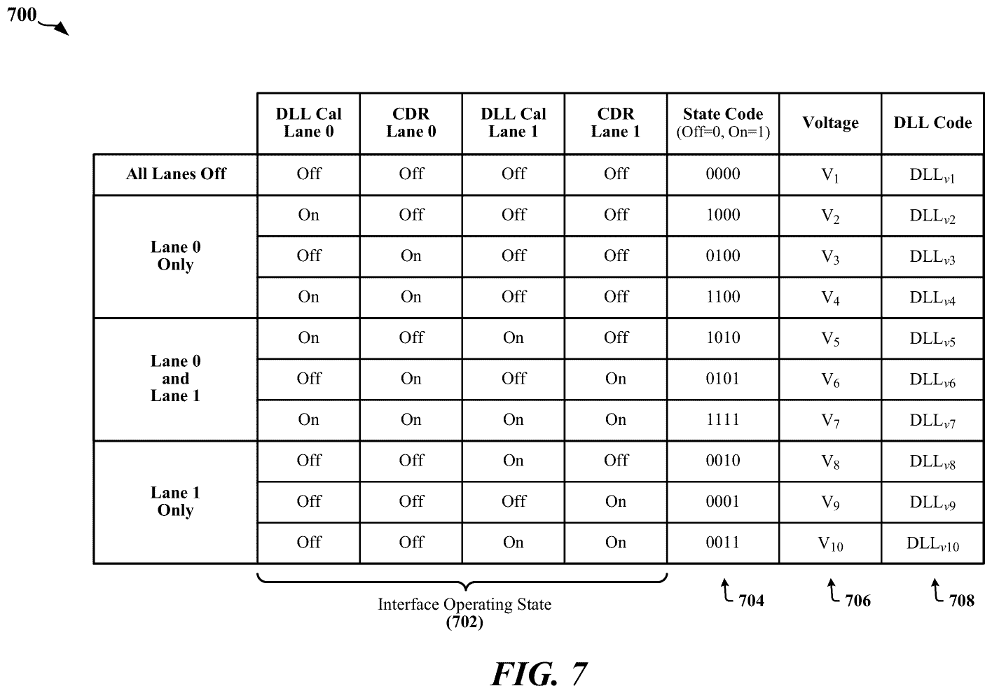

FIG. 7 illustrates an example of a mapping table 700 that maintains DLL calibration codes 708 for various operating states of a data communication interface that is operated in accordance with certain aspects of this disclosure. The DLL calibration codes 708 may be maintained in a lookup table and indexed using a reference that relates each DLL calibration codes 708 with a corresponding operating state. In the illustrated example, each operating state may correspond to the number of data lanes that are active (On), the number of data lanes that are inactive (Off), the combination of active/inactive lanes, or CDR circuits that are active. Different CDR circuits may affect power supply voltage by different amounts and each state may be defined based on which CDR circuits are active. In some implementations, measured power supply voltages may be associated with operating states or operating codes. In some implementations, states are defined for different frequencies of operation of the data communication interface or for different bands of frequencies in which the data communication interface can operate.

At least two fields may be used to index the illustrated mapping table 700. State code 704 in the mapping table 700 is a distillation of the interface operating state 702, and characterizes combinations of active/inactive lanes and active/inactive CDR circuits. The columns included in the interface operating state 702 are duplicative of the state code 704 and may not be included in a look-up table when implemented in a physical circuit. Voltage state 706 may refer to an integer value that is assigned to a measurable voltage level and corresponds to one of the DLL calibration codes 708. In some implementations, measured power supply voltages or voltage ranges may be included as an index that can be used to select DLL calibration codes 708, or to identify voltage state 706.

The illustrated mapping table 700 relates to an example in which the operation of two lanes in the data communication interface are characterized. A controller circuit may be configured to use the DLL codes listed in the mapping table 700 to determine a phase offset in real-time. The illustrated mapping table 700 stores 10 DLL codes (DLLᵥ₁, . . . DLLᵥ₁₀). A compensation offset may be determined in accordance with Eq. 2 and in real time using DLL codes stored in the mapping table 700.

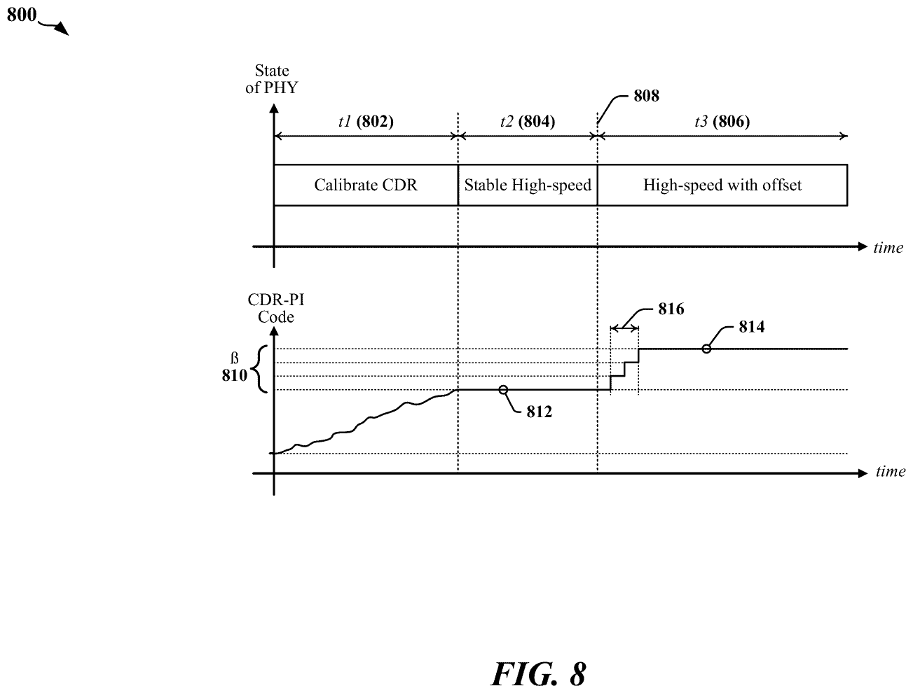

FIG. 8 is a timing diagram 800 that illustrates an example of real-time calibration in accordance with certain aspects of this disclosure. In a first time interval 802, the physical interface of a communication link may be initialized and calibrated. An objective of initial calibration is to achieve CDR lock whereby the CDR, DLL, phase interpolator and associated circuits are configured to maximize reliability of data capture from each data lane of the communication link. A second time interval 804 may commence after the physical interface of the communication link has achieved CDR lock and can operate in a stable manner. The CDR lock may be established when an initial CDR-PI code 812 has been determined. The CDR-PI code 812 defines a phase shift introduced by a phase interpolator into a data recovery clock signal used to capture data from a data signal transmitted over the communication link. In one example, CDR lock is established when edges in the data recovery clock signal occur at the center of the data eye opening such that stable, reliable operation of the communication link can occur.

In the illustrated timing diagram 800, a change in power supply voltage occurs at a point in time 808. In one example, the CDR circuit 232 is turned off and the change in power supply voltage is detected during a recalibration of the DLL 228. In another example, the change in power supply voltage is detected by a voltage measurement circuit. In other examples, the change in power supply voltage may be detected by a circuit or feature of the communication link physical interface, including an error detection circuit or other circuit that monitors sampling clock and data signals. In another example, a controller may indicate the change in power supply voltage when reconfiguring the operational state of the communication link in a manner that is expected to change voltage of the power supply. In the latter example, reconfiguration of operational state that activates or deactivates a data lane or associated CDR circuits can cause the change in power supply voltage.

The controller may cause the phase interpolator to be reconfigured to conform with a compensation offset or a new CDR-PI code 814 determined using Eq. 2. In some instances, the compensation offset or new CDR-PI code 814 may be obtained using a look up table. In the illustrated example, the CDR-PI code is incrementally increased in a number of phase steps (B 810) executed over a period of time 816. At the conclusion of the adjustment, value of the new CDR-PI code 814 is expected to equal the sum of the values of the initial CDR-PI code 812 and B 810.

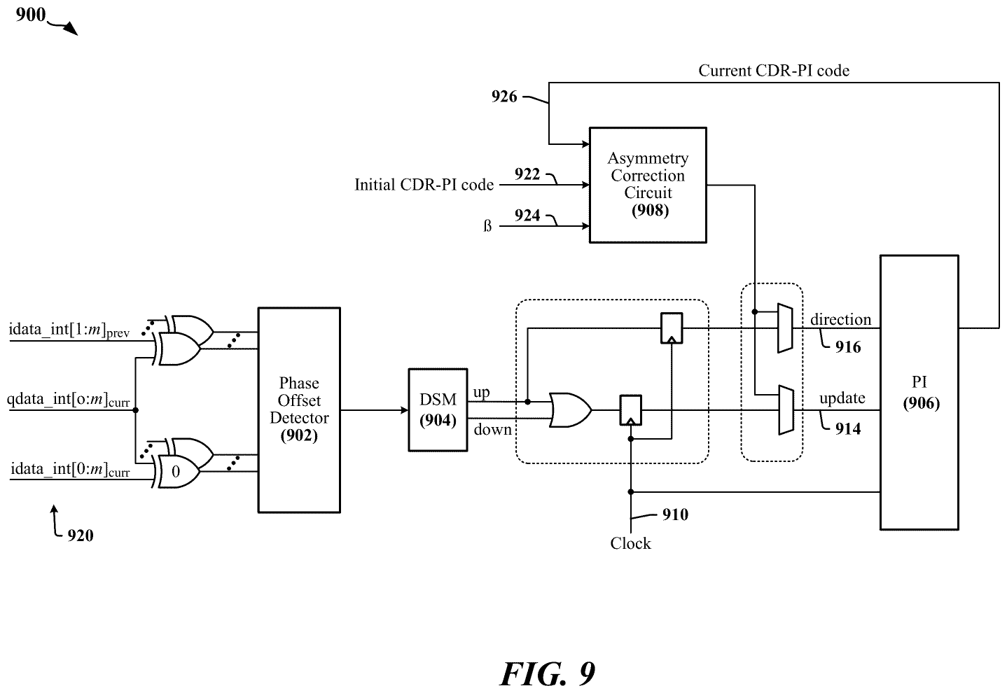

FIG. 9 illustrates certain aspects of a phase control circuit 900 that may be operated in accordance with certain aspects of this disclosure. The phase control circuit 900 is configured to operate after the initial calibration of the CDR, DDR and PI 906. The phase control circuit 900 can change the configuration of a phase interpolator (the PI 906) in order to accommodate changes in communication link physical interface configuration or other detected asymmetry of the CDR eye opening. In one example, the PI 906 may be reconfigured to modify the phase shift applied to a signal received at its input in order to produce a phase shifted output signal that may be used in the capture of data from a data signal transmitted over a data communication link.

In one aspect, the phase control circuit 900 may be configured to manage data capture in a multichannel communication link. The phase control circuit 900 may perform determinations or calculations related to phase offsets using information provided by a look-up table, such as the mapping table 700 illustrated in FIG. 7. The look-up table may maintain a listing of DLL calibration codes 708 for various operating states of the multichannel communication link. In some examples, the phase control circuit 900 may cause a DLL to be reconfigured with a DLL code that corresponds to a new operating state after a transition from a previous operating state has been detected or indicated.

In accordance with various aspects of this disclosure, the asymmetry correction circuit 908 may be configured to modify the phase shift applied by the PI 906 to a signal received at its input in order to produce its phase shifted output signal. In one example, the asymmetry correction circuit 908 receives or accesses an initial CDR-PI code 922 that controls the operation of the PI 906 and an offset value 924 (ß) that represents the difference between the initial CDR-PI code 922 and a new CDR-PI code. In some implementations, the asymmetry correction circuit 908 may cause the new CDR-PI code to be written to the PI 906. In some implementations, the phase shift provided by the PI 906 is updated incrementally in phase-angle steps. In these latter implementations, the asymmetry correction circuit 908 may monitor the current code value 926 used by the PI 906, while providing an update signal 914 that causes the phase-angle to be increased or decreased according to a direction signal 916 that controls whether the phase-angle is increased or decreased. The asymmetry correction circuit 908 may continue modifying the phase shift provided by the PI 906 until the current code value 926 equals the sum of the initial CDR-PI code 922 and B. In some implementations, the timing of the phase-angle steps may be controlled by a clock signal 910.

In accordance with various aspects of this disclosure, the phase control circuit 900 may be configured to fine-tune the CDR eye opening. Fine-tuning may be accomplished using timing information derived from transitions in one or more data signals received over the multichannel communication link. The phase control circuit 900 may compare aggregated timing of rising edges in the data signals with aggregated timing of edges in the data signals. Comparisons of current and previous bit values 920 for a channel may indicate the occurrence of transitions and the directions of those transitions. The transition information is aggregated using a phase offset detector 902 and used to determine whether a rising or falling edge in the clock signal is to be phase shifted. In one example, a delta sigma modulator (DSM 904) may be configured to process the edges and determine or cause a phase shift increment and the direction (±phase angle) of the phase shift increment. The phase shift is incrementally applied using the update signal 914 to control the PI 906. The update signal 914 causes the phase-angle to be increased or decreased according to a direction signal 916 that controls whether the phase-angle is increased or decreased.

In accordance with various aspects of this disclosure, multiple phase interpolators may be used to receive data from a multichannel communication link. In some examples, each lane of the multichannel communication link is associated with a dedicated phase interpolator. A CDR circuit may provide a receive clock signal to control data capture by multiple deserializers. Each deserializer is coupled to one data channel of the multichannel communication link, and a corresponding phase interpolator is used to apply a calibrated phase offset to the receive clock signal and/or to fine-tune the receive clock signal based on timing of transitions in the data signal received from the associated data channel. In some implementations, the phase control circuit 900 can handle phase adjustments for multiple data channels of the multichannel communication link. In some implementations a phase control circuit 900 is provided for each data channel of the multichannel communication link.

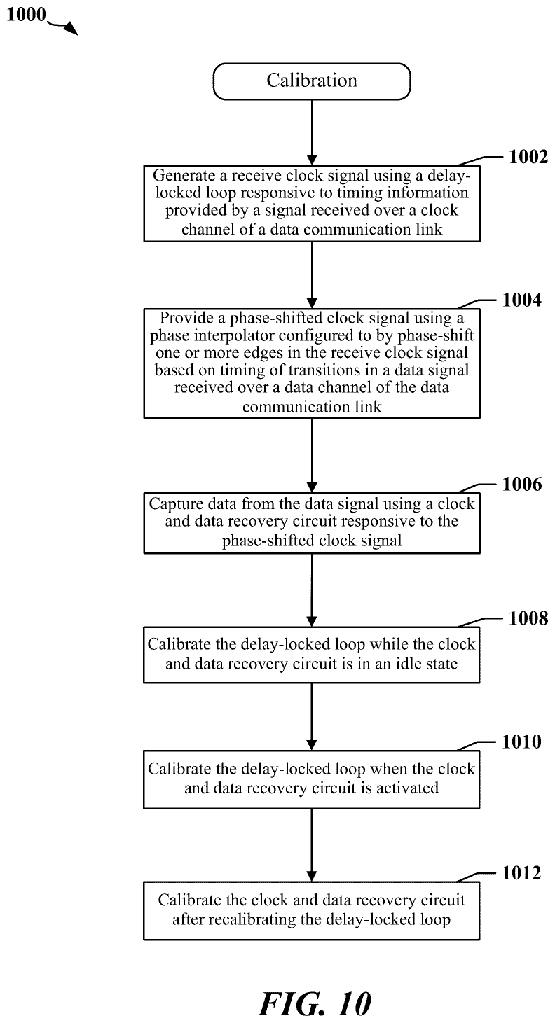

FIG. 10 is a flowchart illustrating an example of a method 1000 for calibrating a data communication interface in accordance with certain aspects disclosed herein. The method 1000 may be implemented in a receiver coupled to data communication link. At block 1002, the receiver generates a receive clock signal using a delay-locked loop responsive to timing information provided by a signal received over a clock channel of a data communication link. At block 1004, the receiver provides a phase-shifted clock signal using a phase interpolator configured to by phase-shift one or more edges in the receive clock signal based on timing of transitions in a data signal received over a data channel of the data communication link. At block 1006, the receiver captures data from the data signal using a clock and data recovery circuit responsive to the phase-shifted clock signal. At block 1008, the receiver calibrates the delay-locked loop while the clock and data recovery circuit is in an idle state. At block 1010, the receiver calibrating the delay-locked loop when the clock and data recovery circuit is activated. At block 1012, the receiver calibrating the clock and data recovery circuit after recalibrating the delay-locked loop.

In certain implementations, the receiver determines a first delay-locked loop calibration code (DLL calibration code) when calibrating the delay-locked loop while the clock and data recovery circuit is in the idle state, determines a second DLL calibration code while recalibrating the delay-locked loop when the clock and data recovery circuit is activated, determines a phase interpolator code based on a difference between the first DLL calibration code and the second DLL calibration code, and uses the phase interpolator code to configure the phase interpolator. The receiver may perform at least one additional recalibration of the delay-locked loop, and determine that a power supply voltage has changed when the at least one additional recalibration produces a third DLL calibration that is different from the second DLL calibration code. The receiver may determine an updated phase interpolator code based on a difference between a current DLL calibration code and an initial DLL calibration code after determining that the power supply voltage has changed, and use the updated phase interpolator code to configure the phase interpolator. In some implementations, the current DLL calibration code and the initial DLL calibration code are included in a table of DLL calibration codes that includes the first DLL calibration code and the second DLL calibration code.

In certain implementations, the receiver determines that the data communication interface has been reconfigured and reconfigures the delay-locked loop using a current DLL calibration code that is selected based on an anticipated change in power supply voltage caused by the reconfiguration of the data communication interface. The receiver may determine an updated phase interpolator code based on a difference between the current DLL calibration code and an initial DLL calibration code after determining that the power supply voltage has changed, and use the updated phase interpolator code to configure the phase interpolator. The delay-locked loop is configured with the initial DLL calibration code before the reconfiguration of the data communication interface. In some examples, the data communication link includes a plurality of data channels. The table of DLL calibration codes may map DLL calibration codes to a plurality of data communication link configurations. In some instances, reconfiguration of the data communication interface causes one or more plurality of data channels to be deactivated or causes one or more plurality of data channels to be activated.

In certain implementations, the receiver is configured to incrementally adjust the phase of the phase-shifted clock signal provided by the phase interpolator independently. Phase shifts added to the receive clock signal by a plurality of phase interpolators may be adjusted independently of one another.

The operational steps described in any of the exemplary aspects herein are described to provide examples. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering. In certain aspects, an apparatus includes means for generating a receive clock signal, including a delay-locked loop responsive to timing information provided by a signal received over a clock channel of a data communication link; means for providing a phase-shifted clock signal, including a phase interpolator configured to by phase-shift one or more edges in the receive clock signal based on timing of transitions in a data signal received over a data channel of the data communication link; means for capturing data from the data signal, including a clock and data recovery circuit responsive to the phase-shifted clock signal; and means for calibrating one or more circuits of the apparatus. The means for calibrating may be configured to calibrate the delay-locked loop while the clock and data recovery circuit is in an idle state, recalibrate the delay-locked loop when the clock and data recovery circuit is activated and calibrate the clock and data recovery circuit after recalibrating the delay-locked loop.

In some examples, the means for calibrating is further configured to determine a first DLL calibration code when calibrating the delay-locked loop while the clock and data recovery circuit is in the idle state, determine a second DLL calibration code while recalibrating the delay-locked loop when the clock and data recovery circuit is activated, determine a phase interpolator code based on a difference between the first DLL calibration code and the second DLL calibration code, and use the phase interpolator code to configure the phase interpolator. The means for calibrating may be further configured to perform at least one additional recalibration of the delay-locked loop, and determine that a power supply voltage has changed when the at least one additional recalibration produces a third DLL calibration that is different from the second DLL calibration code. The means for calibrating may be further configured to determine an updated phase interpolator code based on a difference between a current DLL calibration code and an initial DLL calibration code after determining that the power supply voltage has changed, and use the updated phase interpolator code to configure the phase interpolator. The current DLL calibration code and the initial DLL calibration code may be included in a table of DLL calibration codes that includes the first DLL calibration code and the second DLL calibration code.

In some examples, the means for calibrating is further configured to determine that the data communication interface has been reconfigured, and reconfigure the delay-locked loop using a current DLL calibration code that is selected based on an anticipated change in power supply voltage caused by the reconfiguration of the data communication interface. The means for calibrating may be further configured to determine an updated phase interpolator code based on a difference between the current DLL calibration code and an initial DLL calibration code after determining that the power supply voltage has changed, and use the updated phase interpolator code to configure the phase interpolator. The delay-locked loop may be configured with the initial DLL calibration code before the reconfiguration of the data communication interface. The data communication link can include a plurality of data channels. The table of DLL calibration codes may map DLL calibration codes to a plurality of data communication link configurations. Reconfiguration of the data communication interface may cause one or more of the plurality of data channels to be deactivated or may cause one or more of the plurality of data channels to be activated.

In certain examples, the means for calibrating is further configured to incrementally adjust the phase of the phase-shifted clock signal provided by the phase interpolator independently. Phase shifts added to the receive clock signal by a plurality of phase interpolators may be adjusted independently of one another.

Some implementation examples are described in the following numbered clauses:
1. A data communication interface comprising: a delay-locked loop configured to generate a receive clock signal based on timing information provided by a signal received over a clock channel of a data communication link; a phase interpolator configured to provide a phase-shifted clock signal by phase-shifting one or more edges in the receive clock signal based on timing of transitions in a data signal received over a data channel of the data communication link; a clock and data recovery circuit configured to capture data from the data signal using the phase-shifted clock signal; and a calibration circuit configured to: calibrate the delay-locked loop while the clock and data recovery circuit is in an idle state; recalibrate the delay-locked loop when the clock and data recovery circuit is activated; and calibrate the clock and data recovery circuit after recalibrating the delay-locked loop.
2. The data communication interface as described in clause 1, wherein the calibration circuit is further configured to: determine a first delay-locked loop calibration code (DLL calibration code) when calibrating the delay-locked loop while the clock and data recovery circuit is in the idle state; determine a second DLL calibration code while recalibrating the delay-locked loop when the clock and data recovery circuit is activated; determine a phase interpolator code based on a difference between the first DLL calibration code and the second DLL calibration code; and use the phase interpolator code to configure the phase interpolator.
3. The data communication interface as described in clause 2, wherein the calibration circuit is further configured to: perform at least one additional recalibration of the delay-locked loop; and determine that a power supply voltage has changed when the at least one additional recalibration produces a third DLL calibration that is different from the second DLL calibration code.
4. The data communication interface as described in clause 3, wherein the calibration circuit is further configured to: determine an updated phase interpolator code based on a difference between a current DLL calibration code and an initial DLL calibration code after determining that the power supply voltage has changed; and use the updated phase interpolator code to configure the phase interpolator.
5. The data communication interface as described in clause 4, wherein the current DLL calibration code and the initial DLL calibration code are included in a table of DLL calibration codes that includes the first DLL calibration code and the second DLL calibration code.
6. The data communication interface as described in any of clauses 1-5, wherein the calibration circuit is further configured to: determine that the data communication interface has been reconfigured; and reconfigure the delay-locked loop using a current DLL calibration code that is selected based on an anticipated change in power supply voltage caused by the reconfiguration of the data communication interface.
7. The data communication interface as described in clause 6, wherein the calibration circuit is further configured to: determine an updated phase interpolator code based on a difference between the current DLL calibration code and an initial DLL calibration code after determining that the power supply voltage has changed; and use the updated phase interpolator code to configure the phase interpolator, wherein the delay-locked loop is configured with the initial DLL calibration code before the reconfiguration of the data communication interface.
8. The data communication interface as described in clause 6 or clause 7, wherein the data communication link comprises a plurality of data channels, and wherein a table of DLL calibration codes that includes the current DLL calibration code and the initial DLL calibration code maps DLL calibration codes to a plurality of data communication link configurations.
9. The data communication interface as described in clause 8, wherein reconfiguration of the data communication interface causes one or more of the plurality of data channels to be deactivated or causes one or more of the plurality of data channels to be activated.
10. The data communication interface as described in any of clauses 1-9, wherein the calibration circuit is further configured to: incrementally adjust a phase of the phase-shifted clock signal provided by the phase interpolator independently, wherein phase shifts added to the receive clock signal by a plurality of phase interpolators are adjusted independently of one another.
11. An apparatus comprising: means for generating a receive clock signal, including a delay-locked loop responsive to timing information provided by a signal received over a clock channel of a data communication link; means for providing a phase-shifted clock signal, including a phase interpolator configured to by phase-shift one or more edges in the receive clock signal based on timing of transitions in a data signal received over a data channel of the data communication link; means for capturing data from the data signal, including a clock and data recovery circuit responsive to the phase-shifted clock signal; and means for calibrating one or more circuits of the apparatus, configured to: calibrate the delay-locked loop while the clock and data recovery circuit is in an idle state; recalibrate the delay-locked loop when the clock and data recovery circuit is activated; and calibrate the clock and data recovery circuit after recalibrating the delay-locked loop.
12. The apparatus as described in clause 11, wherein the means for calibrating is further configured to: determine a first delay-locked loop calibration code (DLL calibration code) when calibrating the delay-locked loop while the clock and data recovery circuit is in the idle state; determine a second DLL calibration code while recalibrating the delay-locked loop when the clock and data recovery circuit is activated; determine a phase interpolator code based on a difference between the first DLL calibration code and the second DLL calibration code; and use the phase interpolator code to configure the phase interpolator.
13. The apparatus as described in clause 12, wherein the means for calibrating is further configured to: perform at least one additional recalibration of the delay-locked loop; and determine that a power supply voltage has changed when the at least one additional recalibration produces a third DLL calibration that is different from the second DLL calibration code.
14. The apparatus as described in clause 13, wherein the means for calibrating is further configured to: determine an updated phase interpolator code based on a difference between a current DLL calibration code and an initial DLL calibration code after determining that the power supply voltage has changed; and use the updated phase interpolator code to configure the phase interpolator.
15. The apparatus as described in clause 14, wherein the current DLL calibration code and the initial DLL calibration code are included in a table of DLL calibration codes that includes the first DLL calibration code and the second DLL calibration code.
16. The apparatus as described in any of clauses 11-15, wherein the means for calibrating is further configured to: determine that the data communication interface has been reconfigured; and reconfigure the delay-locked loop using a current DLL calibration code that is selected based on an anticipated change in power supply voltage caused by the reconfiguration of the data communication interface.
17. The apparatus as described in clause 16, wherein the means for calibrating is further configured to: determine an updated phase interpolator code based on a difference between the current DLL calibration code and an initial DLL calibration code after determining that the power supply voltage has changed; and use the updated phase interpolator code to configure the phase interpolator, wherein the delay-locked loop is configured with the initial DLL calibration code before the reconfiguration of the data communication interface.
18. The apparatus as described in clause 16 or clause 17, wherein the data communication link comprises a plurality of data channels, and wherein a table of DLL calibration codes that includes the current DLL calibration code and the initial DLL calibration code maps DLL calibration codes to a plurality of data communication link configurations.
19. The apparatus as described in clause 18, wherein reconfiguration of the data communication interface causes one or more of the plurality of data channels to be deactivated or causes one or more of the plurality of data channels to be activated.
20. The apparatus as described in any of clauses 11-19, wherein the means for calibrating is further configured to: incrementally adjust a phase of the phase-shifted clock signal provided by the phase interpolator independently, wherein phase shifts added to the receive clock signal by a plurality of phase interpolators are adjusted independently of one another.
21. A method for calibrating a data communication interface comprising: generating a receive clock signal using a delay-locked loop responsive to timing information provided by a signal received over a clock channel of a data communication link; providing a phase-shifted clock signal using a phase interpolator configured to by phase-shift one or more edges in the receive clock signal based on timing of transitions in a data signal received over a data channel of the data communication link; capturing data from the data signal using a clock and data recovery circuit responsive to the phase-shifted clock signal; calibrating the delay-locked loop while the clock and data recovery circuit is in an idle state; calibrating the delay-locked loop when the clock and data recovery circuit is activated; and calibrating the clock and data recovery circuit after recalibrating the delay-locked loop.
22. The method as described in clause 21, further comprising: determining a first delay-locked loop calibration code (DLL calibration code) when calibrating the delay-locked loop while the clock and data recovery circuit is in the idle state; determining a second DLL calibration code while recalibrating the delay-locked loop when the clock and data recovery circuit is activated; determining a phase interpolator code based on a difference between the first DLL calibration code and the second DLL calibration code; and using the phase interpolator code to configure the phase interpolator.
23. The method as described in clause 22, further comprising: performing at least one additional recalibration of the delay-locked loop; and determining that a power supply voltage has changed when the at least one additional recalibration produces a third DLL calibration that is different from the second DLL calibration code.
24. The method as described in clause 23, further comprising: determining an updated phase interpolator code based on a difference between a current DLL calibration code and an initial DLL calibration code after determining that the power supply voltage has changed; and using the updated phase interpolator code to configure the phase interpolator.
25. The method as described in clause 24, wherein the current DLL calibration code and the initial DLL calibration code are included in a table of DLL calibration codes that includes the first DLL calibration code and the second DLL calibration code.
26. The method as described in any of clauses 21-25, further comprising: determining that the data communication interface has been reconfigured; and reconfiguring the delay-locked loop using a current DLL calibration code that is selected based on an anticipated change in power supply voltage caused by the reconfiguration of the data communication interface.
27. The method as described in clause 26, further comprising: determining an updated phase interpolator code based on a difference between the current DLL calibration code and an initial DLL calibration code after determining that the power supply voltage has changed; and using the updated phase interpolator code to configure the phase interpolator, wherein the delay-locked loop is configured with the initial DLL calibration code before the reconfiguration of the data communication interface.
28. The method as described in clause 26 or clause 27, wherein the data communication link comprises a plurality of data channels, and wherein a table of DLL calibration codes that includes the current DLL calibration code and the initial DLL calibration code maps DLL calibration codes to a plurality of data communication link configurations.
29. The method as described in clause 28, wherein reconfiguration of the data communication interface causes one or more of the plurality of data channels to be deactivated or causes one or more of the plurality of data channels to be activated.
30. The method as described in any of clauses 21-29, further comprising: incrementally adjusting a phase of the phase-shifted clock signal provided by the phase interpolator independently, wherein phase shifts added to the receive clock signal by a plurality of phase interpolators are adjusted independently of one another.

As used herein, a phrase referring to “at least one of a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The present disclosure is provided to enable any person skilled in the art to make or use aspects of the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A data communication interface comprising:
a delay-locked loop (DLL) configured to generate a receive clock signal based on timing information provided by a signal received over a clock channel of a data communication link;
a phase interpolator configured to provide a phase-shifted clock signal by phase-shifting one or more edges in the receive clock signal based on timing of transitions in a data signal received over a data channel of the data communication link;
a clock and data recovery (CDR) circuit configured to capture data from the data signal using the phase-shifted clock signal; and
a controller configured to:
execute a DLL delay calibration loop to determine a first DLL calibration code that causes the delay-locked loop to generate the receive clock signal with a desired phase shift while the clock and data recovery circuit is in an idle state, thereby calibrating the delay-locked loop;
recalibrate the delay-locked loop when the clock and data recovery circuit is activated; and
calibrate the clock and data recovery circuit after recalibrating the delay-locked loop by determining a CDR code that causes the clock and data recovery circuit to configure timing of edges in the phase-shifted clock signal.

2. The data communication interface of claim 1, wherein the controller is further configured to:
determine a second DLL calibration code while recalibrating the delay-locked loop when the clock and data recovery circuit is activated;
determine a phase interpolator code based on a difference between the first DLL calibration code and the second DLL calibration code; and
use the phase interpolator code to configure the phase interpolator.

3. The data communication interface of claim 2, wherein the controller is further configured to:
perform at least one additional recalibration of the delay-locked loop; and
determine that a power supply voltage has changed when the at least one additional recalibration produces a third DLL calibration code that is different from the second DLL calibration code.

4. The data communication interface of claim 3, wherein the controller is further configured to:
determine an updated phase interpolator code based on a difference between a current DLL calibration code and an initial DLL calibration code after determining that the power supply voltage has changed; and
use the updated phase interpolator code to configure the phase interpolator.

5. The data communication interface of claim 4, wherein the current DLL calibration code and the initial DLL calibration code are included in a table of DLL calibration codes that includes the first DLL calibration code and the second DLL calibration code.

6. The data communication interface of claim 1, wherein the controller is further configured to:
determine that the data communication interface has been reconfigured; and
reconfigure the delay-locked loop using a current DLL calibration code that is selected based on an anticipated change in power supply voltage caused by the reconfiguration of the data communication interface.

7. The data communication interface of claim 6, wherein the controller is further configured to:
determine an updated phase interpolator code based on a difference between the current DLL calibration code and an initial DLL calibration code after determining that the power supply voltage has changed; and
use the updated phase interpolator code to configure the phase interpolator,
wherein the delay-locked loop is configured with the initial DLL calibration code before the reconfiguration of the data communication interface.

8. The data communication interface of claim 7, wherein the data communication link comprises a plurality of data channels, and wherein a table of DLL calibration codes that includes the current DLL calibration code and the initial DLL calibration code maps DLL calibration codes to a plurality of data communication link configurations.

9. The data communication interface of claim 8, wherein reconfiguration of the data communication interface causes one or more of the plurality of data channels to be deactivated or causes one or more of the plurality of data channels to be activated.

10. The data communication interface of claim 1, wherein the controller is further configured to:
incrementally adjust a phase of the phase-shifted clock signal provided by the phase interpolator independently, wherein phase shifts added to the receive clock signal by a plurality of phase interpolators are adjusted independently of one another.

11. An apparatus comprising:
means for generating a receive clock signal, including a delay-locked loop responsive to timing information provided by a signal received over a clock channel of a data communication link;
means for providing a phase-shifted clock signal, including a phase interpolator configured to by phase-shift one or more edges in the receive clock signal based on timing of transitions in a data signal received over a data channel of the data communication link;
means for capturing data from the data signal, including a clock and data recovery circuit responsive to the phase-shifted clock signal; and
means for calibrating one or more circuits of the apparatus, including a controller configured to:
calibrate the delay-locked loop by executing a DLL delay calibration loop to determine a first DLL calibration code that causes the delay-locked loop to generate the receive clock signal with a desired phase shift while the clock and data recovery circuit is in an idle state;
recalibrate the delay-locked loop when the clock and data recovery circuit is activated; and
calibrate the clock and data recovery circuit after recalibrating the delay-locked loop by determining a CDR code that causes the clock and data recovery circuit to configure timing of edges in the phase-shifted clock signal.

12. The apparatus of claim 11, wherein the controller is further configured to:
determine a second DLL calibration code while recalibrating the delay-locked loop when the clock and data recovery circuit is activated;
determine a phase interpolator code based on a difference between the first DLL calibration code and the second DLL calibration code; and
use the phase interpolator code to configure the phase interpolator.

13. The apparatus of claim 12, wherein the controller is further configured to:
perform at least one additional recalibration of the delay-locked loop; and
determine that a power supply voltage has changed when the at least one additional recalibration produces a third DLL calibration that is different from the second DLL calibration code.

14. The apparatus of claim 13, wherein the controller is further configured to:
determine an updated phase interpolator code based on a difference between a current DLL calibration code and an initial DLL calibration code after determining that the power supply voltage has changed; and
use the updated phase interpolator code to configure the phase interpolator.

15. The apparatus of claim 14, wherein the current DLL calibration code and the initial DLL calibration code are included in a table of DLL calibration codes that includes the first DLL calibration code and the second DLL calibration code.

16. The apparatus of claim 11, wherein the controller is further configured to:
determine that the apparatus has been reconfigured; and
reconfigure the delay-locked loop using a current DLL calibration code that is selected based on an anticipated change in power supply voltage caused by the reconfiguration of the apparatus.

17. The apparatus of claim 16, wherein the controller is further configured to:
determine an updated phase interpolator code based on a difference between the current DLL calibration code and an initial DLL calibration code after determining that the power supply voltage has changed; and
use the updated phase interpolator code to configure the phase interpolator,
wherein the delay-locked loop is configured with the initial DLL calibration code before the reconfiguration of the apparatus.

18. The apparatus of claim 17, wherein the data communication link comprises a plurality of data channels, and wherein a table of DLL calibration codes that includes the current DLL calibration code and the initial DLL calibration code maps DLL calibration codes to a plurality of data communication link configurations.

19. The apparatus of claim 18, wherein reconfiguration of the apparatus causes one or more of the plurality of data channels to be deactivated or causes one or more of the plurality of data channels to be activated.

20. The apparatus of claim 11, wherein the controller is further configured to:
incrementally adjust a phase of the phase-shifted clock signal provided by the phase interpolator independently, wherein phase shifts added to the receive clock signal by a plurality of phase interpolators are adjusted independently of one another.

21. A method for calibrating a data communication interface comprising:
generating a receive clock signal using a delay-locked loop responsive to timing information provided by a signal received over a clock channel of a data communication link;
providing a phase-shifted clock signal using a phase interpolator configured to by phase-shift one or more edges in the receive clock signal based on timing of transitions in a data signal received over a data channel of the data communication link;
capturing data from the data signal using a clock and data recovery circuit responsive to the phase-shifted clock signal;
calibrating the delay-locked loop by executing a DLL delay calibration loop to determine a first DLL calibration code that causes the delay-locked loop to generate the receive clock signal with a desired phase shift while the clock and data recovery circuit is in an idle state;
recalibrating the delay-locked loop when the clock and data recovery circuit is activated; and
calibrating the clock and data recovery circuit after recalibrating the delay-locked loop by determining a CDR code that causes the clock and data recovery circuit to configure timing of edges in the phase-shifted clock signal.

22. The method of claim 21, further comprising:
determining a second DLL calibration code while recalibrating the delay-locked loop when the clock and data recovery circuit is activated;
determining a phase interpolator code based on a difference between the first DLL calibration code and the second DLL calibration code; and
using the phase interpolator code to configure the phase interpolator.

23. The method of claim 22, further comprising:
performing at least one additional recalibration of the delay-locked loop; and
determining that a power supply voltage has changed when the at least one additional recalibration produces a third DLL calibration that is different from the second DLL calibration code.

24. The method of claim 23, further comprising:
determining an updated phase interpolator code based on a difference between a current DLL calibration code and an initial DLL calibration code after determining that the power supply voltage has changed; and
using the updated phase interpolator code to configure the phase interpolator.

25. The method of claim 24, wherein the current DLL calibration code and the initial DLL calibration code are included in a table of DLL calibration codes that includes the first DLL calibration code and the second DLL calibration code.

26. The method of claim 21, further comprising:
determining that the data communication interface has been reconfigured; and
reconfiguring the delay-locked loop using a current DLL calibration code that is selected based on an anticipated change in power supply voltage caused by the reconfiguration of the data communication interface.

27. The method of claim 26, further comprising:
determining an updated phase interpolator code based on a difference between the current DLL calibration code and an initial DLL calibration code after determining that the power supply voltage has changed; and
using the updated phase interpolator code to configure the phase interpolator,
wherein the delay-locked loop is configured with the initial DLL calibration code before the reconfiguration of the data communication interface.

28. The method of claim 27, wherein the data communication link comprises a plurality of data channels, and wherein a table of DLL calibration codes that includes the current DLL calibration code and the initial DLL calibration code maps DLL calibration codes to a plurality of data communication link configurations.

29. The method of claim 28, wherein reconfiguration of the data communication interface causes one or more of the plurality of data channels to be deactivated or causes one or more of the plurality of data channels to be activated.

30. The method of claim 21, further comprising:
incrementally adjusting a phase of the phase-shifted clock signal provided by the phase interpolator independently, wherein phase shifts added to the receive clock signal by a plurality of phase interpolators are adjusted independently of one another.
